(19) United States
(12) Patent Application Publication
(10) Pub. No.: US 2018/0069142 A1
(43) Pub. Date: Mar. 8, 2018

(54) PHOTOVOLTAIC SOLAR CELL WITH BACKSIDE RESONANT WAVEGUIDE

(71) Applicant: NORTHROP GRUMMAN SYSTEMS CORPORATION, Falls Church, VA (US)

(72) Inventor: PATRICK BRUCKNER SHEA, Alexandria, VA (US)

(73) Assignee: NORTHROP GRUMMAN SYSTEMS CORPORATION, Falls Church, VA (US)

(21) Appl. No.: 15/806,798

(22) Filed: Nov. 8, 2017

Related U.S. Application Data
(62) Division of application No. 15/214,890, filed on Jul. 20, 2016.

(51) Int. Cl. H01L 31/054; H01L 31/18; H01L 31/0236

(52) U.S. Cl. CPC H01L 31/054; H01L 31/18; H01L 31/02363

(57) ABSTRACT

A solar cell has a backside resonant waveguide structure. The backside structure includes a plurality of resonant waveguides formed in or on a semiconductor-based light absorbing material and arranged in a pattern to cause laterally scattered light to be at least partially confined in the semiconductor-based light absorbing material.

This application claims the benefit under 35 U.S.C. § § 120, 121 of the filing date of non-provisional patent application Ser. No. 15/214,890 filed Jul. 20, 2016, the disclosure of which is incorporated herein by reference.

### FIELD OF THE DISCLOSURE

The subject matter of this disclosure relates to the field photovoltaic solar cells, and in particular to solar cells incorporating backside resonant waveguides.

### BACKGROUND

The global energy crisis has placed new demands for creative technologies to provide affordable and renewable energy to an increasing world population. In response to the volatile raw material price of silicon, silicon-based solar cell manufacturers have attempted to reduce the amount of polysilicon used per solar cell simply by thinning the wafers. However, as silicon solar cells are thinned to reduce manufacturing costs, internal reflection and especially backside surface carrier (electron) recombination-related efficiency losses increase rapidly and begin to dominate the performance of conventional silicon solar cells.

As an example, thinning a silicon wafer from 300 μm to 100 μm reduces the sunlight to electricity conversion efficiency from 18.5% to 16.5% for a silicon solar cell constructed using a conventional aluminum Back Surface Field (B SF) due to backside surface recombination of photo-generated carriers. Hence, there is a need to reduce or eliminate backside surface recombination loss of photo-generated carriers in these lower cost thinned silicon solar cells to significantly improve their efficiency.

### SUMMARY

The following presents a simplified summary in order to provide a basic understanding of some aspects described herein. This summary is not an extensive overview of the claimed subject matter. It is intended to neither identify key or critical elements of the claimed subject matter nor delineate the scope thereof. Its sole purpose is to present some concepts in a simplified form as a prelude to the more detailed description that is presented later.

In one embodiment a photovoltaic solar cell is provided. The photovoltaic solar cell comprises: a semiconductor substrate with front and back sides, a surface structure on the front side of the semiconductor substrate, and a backside structure on said back side of said semiconductor substrate. The surface structure on the front side of the semiconductor substrate includes at least one front-side layer and at least one associated front-side contact. The semiconductor substrate comprises at least one semiconductor-based light absorbing material that exhibits a photovoltaic effect. The backside structure includes a plurality of resonant waveguides formed in or on the semiconductor-based light absorbing material. The plurality of resonant waveguides is arranged in a pattern to cause laterally scattered light to be at least partially confined in the semiconductor-based light absorbing material.

In one embodiment, the front-side layer is comprised of an N-type semiconductor and the semiconductor substrate is comprised of a P-type semiconductor. In another embodiment, the front-side layer is comprised of a P-type semiconductor and the semiconductor substrate is comprised of an N-type semiconductor.

In one embodiment, the front-side layer further includes at least one of a glass or plastic cover, an antireflective layer, and an oxide layer. In one embodiment, the front-side contact includes at least one conductive material such that the front-side contact has direct contact with the semiconductor substrate.

In one embodiment, the backside structures also includes a first oxide layer in contact with the semiconductor substrate, a second oxide layer in contact with an overlying conducting and reflecting layer, and a silicon nitride charge storage layer between the first oxide layer and the second oxide layer.

In one embodiment, the semiconductor-based light absorbing material is selected from the group consisting of monocrystalline silicon, polysilicon, multicrystalline silicon, and ribbon silicon. In one embodiment, the solar cell comprises a multi junction solar cell made from a single type of semiconducting material or a combination of semiconducting materials.

In one embodiment, the backside structure exhibits a photovoltaic effect. In one embodiment, the resonant waveguides are etched in the semiconductor substrate. In another embodiment, the resonant waveguides are deposited on the semiconductor substrate.

In one embodiment, the resonant waveguides are arranged in a repeating pattern. In one embodiment, the repeating pattern can be a staggered pattern or an aligned pattern. In another embodiment, at least some of the resonant waveguides are ring-shaped or disc shaped. In another embodiment, at least some of the resonant waveguides have a regular polygon shape. In one embodiment, at least some of the resonant waveguides include at least two concentric rings.

In one embodiment, the backside structure further includes a plurality of oxide-nitride-oxide stacks arranged in a pattern aligned in repeating pattern. In another embodiment, the solar cell further comprises a plurality of gate electrodes formed on the oxide-nitride-oxide stacks.

A method of manufacturing a photovoltaic solar cell with a backside resonant photonic waveguide structure is provided. In one embodiment, the method comprises forming a semiconductor substrate comprising at least one semiconductor-based light absorbing material that exhibits a photovoltaic effect, the semiconductor substrate having a front side and a backside, forming a backside structure comprising a plurality of resonant waveguides arranged in a pattern on the backside of the semiconductor bulk layer, forming at least one semiconductor surface layer on the front side of the semiconductor bulk layer, forming a top electrode on the semiconductor surface layer, and forming a bottom electrode on the backside structure.

In another embodiment, the method further comprises forming a first oxide layer on the backside structure, forming a silicon nitride layer on the first oxide layer, forming a second oxide layer on the nitride layer, and forming the bottom electrode on the second oxide layer.

In one embodiment, the method comprises etching the resonant waveguides into the semiconductor substrate. In another embodiment, the method comprises depositing the resonant waveguides onto the semiconductor substrate.

Other features and characteristics of the subject matter of this disclosure, as well as the methods of operation, functions of related elements of structure and the combination of parts, and economies of manufacture, will become more apparent upon consideration of the following description and the appended claims with reference to the accompanying drawings, all of which form a part of this specification, wherein like reference numerals designate corresponding parts in the various figures.

### BRIEF DESCRIPTION OF THE DRAWINGS

The accompanying drawings, which are incorporated herein and form part of the specification, illustrate various embodiments and, together with the description, further serve to explain the principles of the disclosed subject matter and to enable a person skilled in the pertinent art to make and use the subject matter described herein. In the drawings, like reference numbers indicate identical or functionally similar elements. A more complete appreciation of the subject matter will be understood by reference to the following detailed description when considered in connection with the accompanying drawings, wherein:

FIG. 1 is a top perspective view of photovoltaic solar cell.

FIG. 2 is a representative side-view of a solar cell containing resonant waveguides and oxide-nitride-oxide layers.

FIG. 3A is a partial bottom plan view of a photovoltaic solar cell showing a backside structure of the solar cell and showing a resonant waveguide disposed on the p-silicon region of the solar cell.

FIG. 3B is a cross-section of a portion of the solar cell along the line 3B-3B in FIG. 3A.

FIG. 4A is a bottom plan view of a photovoltaic solar cell showing a backside structure of the solar cell with an aligned pattern of resonant waveguides.

FIG. 4B is a bottom plan view of a photovoltaic solar cell showing a backside structure of the solar cell with a staggered pattern of resonant waveguides.

FIGS. 5A-5C depict typical steps in the manufacture of a solar cell. FIG. 5A represents a solar cell with the oxide-nitride-oxide stack. FIG. 5B shows pattern and etch openings in the oxide-nitride-oxide stack and p+ implantation. FIG. 5C shows deposition of backside electrode and etching of electrode to separate from gate electrode.

FIG. 6A is a photograph of a disc-shaped resonant waveguide with concentric circles made from AlGaAs.

FIG. 6B depicts optical modes of the resonant waveguide of FIG. 6A.

### DETAILED DESCRIPTION

While aspects of the subject matter of the present disclosure may be embodied in a variety of forms, the following description and accompanying drawings are merely intended to disclose some of these forms as specific examples of the subject matter. Accordingly, the subject matter of this disclosure is not intended to be limited to the forms or embodiments so described and illustrated.

Unless defined otherwise, all terms of art, notations and other technical terms or terminology used herein have the same meaning as is commonly understood by one of ordinary skill in the art to which this disclosure belongs. All patents, applications, published applications and other publications referred to herein are incorporated by reference in their entirety. If a definition set forth in this section is contrary to or otherwise inconsistent with a definition set forth in the patents, applications, published applications, and other publications that are herein incorporated by reference, the definition set forth in this section prevails over the definition that is incorporated herein by reference.

Unless otherwise indicated or the context suggests otherwise, as used herein, “a” or “an” means “at least one” or “one or more.”

This description may use relative spatial and/or orientation terms in describing the position and/or orientation of a component, apparatus, location, feature, or a portion thereof. Unless specifically stated, or otherwise dictated by the context of the description, such terms, including, without limitation, top, bottom, above, below, under, on top of, upper, lower, left of, right of, in front of, behind, next to, adjacent, between, horizontal, vertical, diagonal, longitudinal, transverse, radial, axial, etc., are used for convenience in referring to such component, apparatus, location, feature, or a portion thereof in the drawings and are not intended to be limiting.

Furthermore, unless otherwise stated, any specific dimensions mentioned in this description are merely representative of an exemplary implementation of a device embodying aspects of the disclosure and are not intended to be limiting.

Photovoltaic (PV) solar cells are solid-state semiconductor devices that absorb light and convert it into electricity, a phenomenon known as the photovoltaic effect. The semiconducting material absorbs a photon with energy Eₚₕ=1.24/λ, where λ is the photon wavelength. An absorbed photon excites an electron, creating an electron-hole charge carrier pair (where an electron is a negative charge and a hole is a positive charge). A PV solar cell typically contains a p-n junction diode, which creates a built-in, internal electric field. Ideally the photo-generated electron-hole pairs are separated and conducted towards opposite polarity electrodes by the built-in electric field. Electrons are collected by the top solar cell contact into an external circuit; likewise holes are collected at a backside solar cell contact into the external circuit. The process induces both a DC current (I) and a voltage (V) that delivers power (P=I*V) to the external circuit that can be utilized or stored.

The previously described case is ideal and assumes no non-radiative (or lossy) charge carrier recombination within the solar cell wherein the charges cannot be collected at the electrodes. In PV solar cells one of the dominant sources of non-radiative recombination is backside silicon-to-aluminum interface states. A poor interface contains a high density of interface states and produces a high surface recombination velocity (SRV). SRV is a metric of how rapidly charge carriers recombine at the interface and thus are lost to collection by the electrodes. Thus, a solar cell with a high SRV traps more charges and displays lower conversion efficiency, while a solar cell with a low SRV has higher conversion efficiency.

Silicon semiconductor devices, including solar cells, are typically thinned to reduce material costs. However, thinning a PV solar cell exacerbates the deleterious effects of backside SRV by essentially placing more of the volume of the solar cell close to the region affected by high SRV. Due to its electronic and crystalline properties, silicon is a relatively weak photon absorber compared to other semiconductors. Therefore, in thick solar cells, low energy (long 1) photons are typically the only photons absorbed near the backside.

However, as the solar cell is thinned, more photons across the entire light spectrum are absorbed near the backside contact. The cumulative effect in thin solar cells increases the likelihood that photo-generated charge carriers will be lost to surface recombination before they can be collected by the electrodes, thus significantly reducing the amount of light that is converted to usable electrical power.

Surface pinning is a method developed in CCD technology wherein a silicon surface is permanently inverted to its opposite polarity by ‘pinning’ the surface at a fixed potential energy. In CCDs, surface pinning was developed as a means of minimizing the surface generation current by permanently filling surface interface states (which induce a loss mechanism) with free-carriers from the inverted semiconductor. By filling these states, trapping of photogenerated minority charge carriers is reduced. In silicon PV solar cells, the backside of the silicon is typically doped p-type (majority positive charge), meaning that the backside would need to be pinned using electrons by applying a positive voltage to the backside surface using positive charge. Surface pinning techniques using the oxide-nitride-oxide stack described herein are fully described in U.S. Pat. No. 8,822,815, which is hereby incorporated by reference in its entirety.

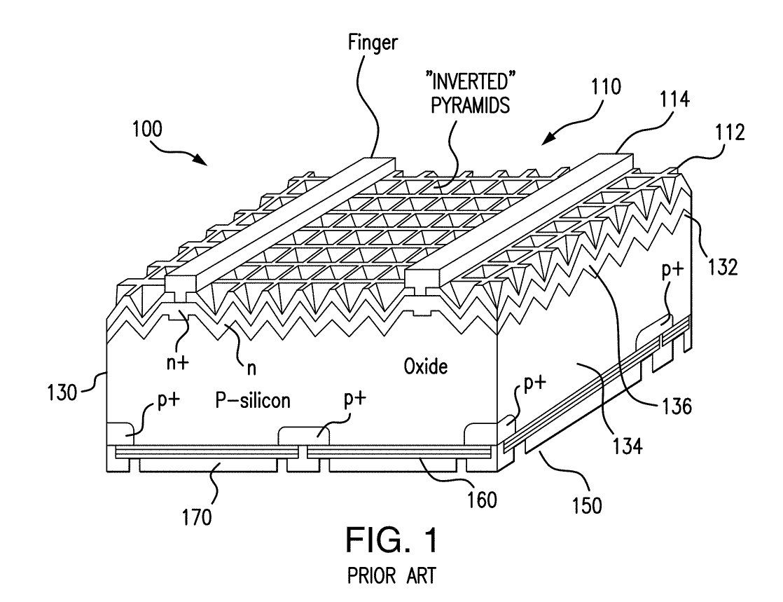

FIG. 1 illustrates the working mechanism of a prior art photovoltaic silicon solar cell 100. In this embodiment, the solar cell 100 includes a surface structure 110 that contains a semiconductor front-side layer 112 and an associated front-side contact 114, a bulk layer 130, and a backside structure 150 that contains an oxide-nitride-oxide nonvolatile charge storage structure, or stack, 160 and a backside contact 170. The semiconductor front-side structure 110 may also include a protective layer (not shown). The bulk layer 130 may be referred to as the semiconductor bulk layer 130.

The surface layer 112 is a protective layer that typically contains a glass or plastic cover or other encapsulant, an antireflective layer, and an oxide layer, such as SiO₂. The front-side contact 114 can be composed of conductive material or a mixture of conductive materials and may have direct contact with the bulk layer 130 to allow electric charges to enter a circuit. In the embodiment shown in FIG. 1, the silicon solar cell 100 includes a plurality of the front-side contacts 114, which may be in the form of elongated parallel strips, referred to as “FINGER” in FIG. 1.

In one embodiment, the bulk layer 130 includes a crystalline silicon layer that is doped with an n-type dopant on one side, forming an n-silicon region 132, and is doped with a p-type dopant on the other side, forming a p-silicon region 134. The border between the N+-silicon region 132 and the p-silicon region 134 is referred to as an N+/p junction 136. The N+/p junction 136 is located so the maximum amount of light is absorbed near the N/+p junction 136. The free electrons generated by light deep in the p-region of the silicon solar cell 100 diffuse to the N+/p junction 136 and separate in the electric field of the junction to produce an open-circuit voltage and a short-circuit current. In addition, holes generated in the N+ region diffuse to the N+/p junction to contribute to the open-circuit voltage and short-circuit current.

The bulk layer 130 may be formed with multiple physical configurations to take advantage of different light absorption and charge separation mechanisms. In one embodiment, the bulk layer 130 has a surface shape of an inverted pyramids array to suppress incident light reflection from the front-side silicon surface.

In one embodiment, the front-side layer is comprised of an N-type semiconductor and the semiconductor substrate is comprised of a P-type semiconductor. In another embodiment, the front-side layer is comprised of a P-type semiconductor and the semiconductor substrate is comprised of an N-type semiconductor.

In one embodiment, the front-side layer further includes at least one of a glass or plastic cover, an antireflective layer, and an oxide layer. In one embodiment, the front-side contact 114 includes at least one conductive material such that the front-side contact has direct contact with the semiconductor substrate.

The oxide-nitride-oxide nonvolatile charge storage structure, or stack, 160 includes a first oxide layer 161 in contact with the semiconductor substrate 134, a second oxide layer 163 in contact with an overlying conducting and reflecting layer, and a silicon nitride charge storage layer 162 between the first oxide layer 161 and the second oxide layer 163.

In one embodiment, the semiconductor-based light absorbing material is selected from the group consisting of monocrystalline silicon, polysilicon, multicrystalline silicon, and ribbon silicon. In one embodiment, the solar cell comprises a multi junction solar cell made from a single type of semiconducting material or a combination of semiconducting materials. Although silicon has been used as the photovoltaic semiconductor medium, those skilled in the art of solar cells will realize other materials, such as compound semiconductors, may be employed, including, but not limited to, cadmium telluride, and copper indium gallium selenide/sulfide.

In some embodiments, the solar cells can comprise multi junction solar cells, having multiple p-n junctions made of any of the semi-conducting materials known in the art or described herein. In some embodiments, the solar cells can comprise organic solar cells, which can comprise organic conductive polymers including, but not limited to, CN-PPV, poly(phenylene vinylene) (PPV), phthalocyanine, polyacetylene, and MEH-PPV. The multi junction and organic solar cells can be manufactured by processes known in the art.

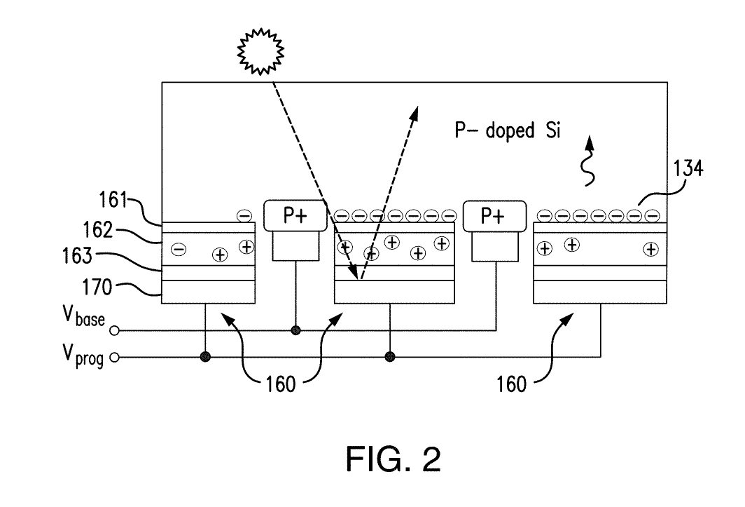

FIG. 2 depicts in side view details of the oxide-nitride-oxide (“ONO”) stacks 160 on the back side 152 of solar cell 100. Each stack 160 constitutes a nonvolatile charge storage structure of the backside structure 150 of the solar cell 100. As described above, in one embodiment, the oxide-nitride-oxide nonvolatile charge storage structure, or stack, 160 includes a first oxide layer 161 (also known as the tunnel oxide layer) that is in contact with the p-silicon region 134, a second oxide layer 163 that is in contact with the backside contact 170, and a silicon nitride charge storage layer 162 between the first oxide layer 161 and the second oxide layer 163. The silicon nitride charge storage layer 162 may be referred to as the nitride layer 162. The interface between the p-silicon region 134 and the first oxide layer 161 is referred to as a backside silicon interface 138, which may also be referred to as the backside interface 138 or backside surface 138. The backside structure 150 is programmed to pin the backside silicon interface 138 in a manner that is similar to the surface pinning technique used in low light level charge couple devices (CCDs).

The backside structure 150 is programmed by applying a large negative bias or programming voltage (V_{prog}) to the backside contact 170 and grounding a base contact 172 (V_{base}). The base contact 172 is the common electrode that collects photo-generated holes and is electrically connected to the external load. With a large enough electric field supplied by the negative gate bias, positively charged holes are able to quantum-mechanically tunnel from the silicon, through the tunnel oxide layer 161, and into the nitride charge storage layer 162. This tunneling process is described, for example, in the article by Marvin H. White, Dennis A. Adams and Jiankang Bu, “On the Go with SONOS”, IEEE Circuits and Devices, Vol. 16, No. 4, July 2000, which is incorporated by reference herein. The programming time is typically less than one second and may be either permanent for the life of the solar cell product or altered at a future date. The stored positive charges in the nitride charge storage layer 162 provide the needed “permanent” biasing to invert or pin the backside interface 138. The pinned backside interface 138 fill surface states or ‘traps’ with electrons (e.g., minority carriers) to electrostatically repel photo-generated electrons, thereby effectively eliminating the loss of photo-generated carriers due to backside recombination. An additional benefit of the backside structure 150 is the improved internal reflectivity of the incident light from the backside interface 138 through constructive interference, thereby allowing more of the incident light to be absorbed as the light makes multiple passes through the silicon solar cell 100 in the bulk layer 130.

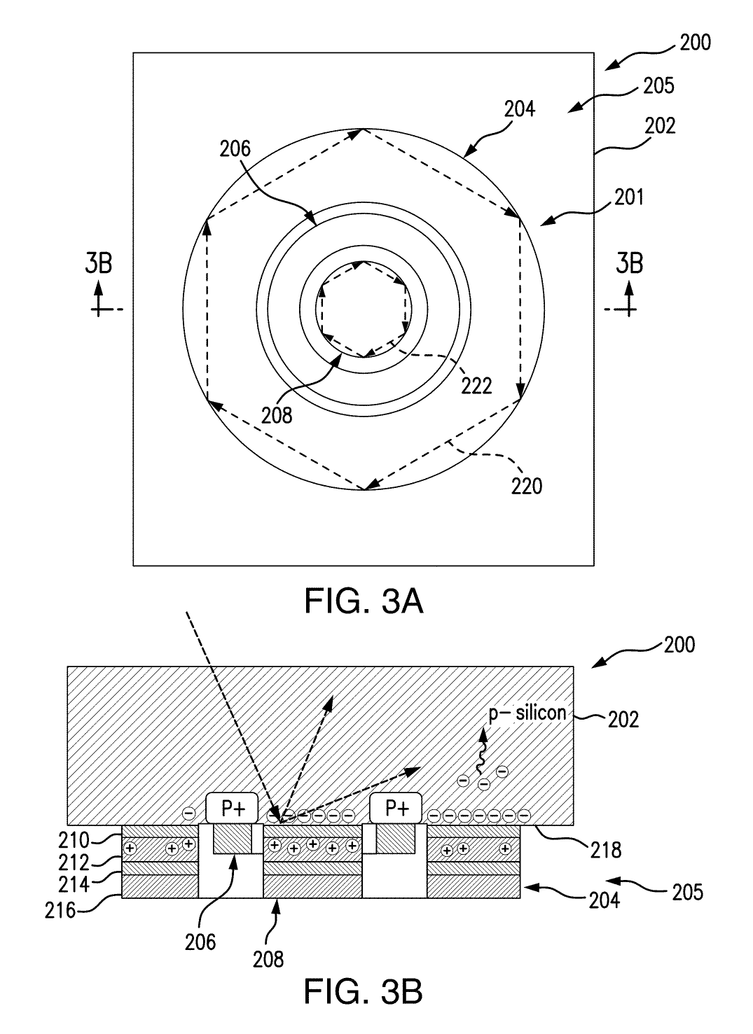

FIGS. 3A and 3B show an embodiment of a photovoltaic solar cell 200 in which one or more of the ONO stacks is formed so as to have the geometry of one or more resonant waveguides. FIG. 3A is a partial bottom plan view showing a backside structure 205 of the solar cell 200 and showing a resonant waveguide 201 disposed on the p-silicon region 202 of the solar cell 200. In the illustrated embodiment, the resonant waveguide 201 comprises a first ring 204 and a second ring 208 (e.g., a cylinder) that is formed concentrically with the first ring 204. FIG. 3B is a cross-section of a portion of the solar cell 200 along the line 3B-3B in FIG. 3A. As shown in FIG. 3B, each ring 204, 208 of the waveguide 201 comprises a separate ONO stack. As described above with respect to FIG. 2, each ONO stack comprises a first oxide layer 210, a nitride layer 212, a second oxide layer 214, and a backside contact layer 216.

The waveguide structures, such as rings 204 and 208 comprising the ONO stacks, may be formed by patterned lithography techniques as described herein and as described in U.S. Pat. No. 8,822,815.

The solar cell 200 may further include a base contact 206 formed as a ring between consecutive rings forming the waveguide structure 201 (e.g., between rings 204, 208 in the illustrated embodiment). The backside structure 205 may be programmed as described above with respect to FIG. 2 thereby forming a backside silicon interface 218.

As shown in FIG. 3B, at least a portion of the incident light, indicated by the dashed arrows, penetrating the p-silicon region 202 is reflected back into the region 202 at the backside silicon interface 218. Due to the effects of the waveguide structures 201, however, some or all of the reflected light maybe infinitely or nearly infinitely retained within the portions of the silicon region 202 covered by resonant waveguide structures. In the case of an embodiment such as shown in FIGS. 3A and 3B, in which the resonant waveguide structures comprise concentric rings, this is represented in FIG. 3B by dashed arrows 220 representing light retained by total internal reflection within the portion of p-silicon region 202 overlapped by ring 204 and dashed arrows 222 representing light retained by total internal reflection within the portion of p-silicon region 202 overlapped by ring 208.

Photonic waveguide structures rely on the optoelectronic properties of their component semiconductor and insulating materials to efficiently transport light from one point to another, typically over long distances with minimal signal degeneration. In the most common example, fiber optic wires are designed as a sleeve of insulators able to transmit an optical signal several hundreds of kilometers while maintaining signal integrity, before and after which the optical signal is generated or received using a solid-state semiconductor device that efficiently processes the light signal and converts it from or into an electrical signal. The refractive index is the property of the waveguiding material that is of interest in photonics; it is a measure of how much the speed of light is reduced in a material as compared to in a vacuum. A vacuum has a refractive index (n) of 1.0. Glass, or silicon dioxide, has an n=1.4; silicon has n=4.0; and silicon nitride has n=2.0. Typically a more dense material has a higher refractive index. Light incident on an interface of two materials with dissimilar refractive indices will reflect according to Snell's law, which is governed by the equation:

$$\frac{sin {θ}_{1}}{sin {θ}_{2}} = \frac{{v}_{1}}{{v}_{2}} = \frac{{λ}_{1}}{{λ}_{2}} = \frac{{n}_{2}}{{n}_{1}}$$

Where, each θ₁ and θ₂ is the angle measured from the normal of the boundary, ν₁ and ν₂ are the velocities of light in the respective media, λ₁ and λ₂ are the wavelengths of light in the respective media, and n₁ and n₂ are the refractive indices of the respective media.

In the case of photonic waveguides, such as a Si rib resonant waveguide structure (i.e., a raised rib of Si defined by straight grooves formed on opposite sides of the rib), light coupled into the silicon from an optical fiber will travel and be confined in the Si rib if the angle at which light hits the Si—SiO₂ interface does not exceed the critical angle; otherwise it experiences total internal reflection. This is known as “index guiding,” or “guided mode resonance.” In various embodiments described herein, the resonant structure has eigenvalues determined by its shape and refractive index wherein light can travel efficiently. The varying combination of air and semiconductor over different regions creates different “effective refractive indices” within the p-silicon region. In the Si rib waveguide, for example, the Si is etched down to form a ridge or raised rib. Light coupled into the Si prefers to travel underneath the rib because the effective refractive index is higher in the rib than in the areas underneath the etched surface, thereby confining the light to the rib.

Certain prior approaches involve optimizing the photonic backside structure using passive two-dimensional, rectangular or pyramidal distributed Bragg reflector (DBR) and reflector patterns and coatings or integrating a photonic bandgap crystal on the backside that acts as an effective reflector and recombination layer. However, these are all passive approaches with no predetermined placement or organization to the enhancing feature and thus achieved marginal efficacy. By incorporating resonant waveguide structures into a solar cell a solar cell is created where the efficiency is limited not by the device, but by the thermal properties of the semiconductor.

The solar cell disclosed herein with backside resonant waveguides solves the seemingly mutually exclusive goals in Si solar cells of achieving maximum light absorption while reducing the solar cell thickness to a cost-reducing minimum. In planar Si solar cells, relatively thick Si was initially used to maximize the amount of material able to absorb incident light. To increase the number of devices that could be made from a given thickness of silicon (and hence increase the cost efficiency), solar cells were made increasingly thinner. However, in doing so, there is less Si volume to absorb light. Existing Si solar cells incorporate backside reflective layers to increase the number of “round-trips” a photon can make through the Si before being absorbed, while also using a randomly-textured backside to laterally scatter light and increase the absorption length to the lateral dimensions of the solar cell. These ideas, however, are still limited by their finite geometries.

The formation of the present resonant photonic waveguide on the solar cell backside induces lateral scattering of light in the cell at the backside interface. The lateral scattering is induced through the principal of Bragg reflection and grating. That is, an incident photon on a ribbed surface does not reflect at necessarily the same angle it is incident on a surface. The laterally scattered light at the Si backside is collected by total internal reflection within the resonantly shaped waveguide (such as one or more rings or a disk) and coupled into the optical modes of the structure effectively offering an infinite absorption length over which photons can be efficiently absorbed. Therefore, one can fabricate an Si solar cell with as thin a volume as mechanically can be handled during the manufacturing process, without sacrificing high absorption or reflective surfaces. Furthermore, to compensate for the backside surface recombination that dominates Si solar cell performance in thin cells, active passivation techniques described in U.S. Pat. No. 8,822,815 can be integrated into the solar cell structure.

A photovoltaic solar cell according to one embodiment comprises: a semiconductor substrate with front and back sides, a surface structure on the front side of the semiconductor substrate, and a backside structure on said back side of said semiconductor substrate. The surface structure on the front side of the semiconductor substrate includes at least one front-side layer and at least one associated front-side contact. The semiconductor substrate comprises at least one semiconductor-based light absorbing material that exhibits a photovoltaic effect. The backside structure includes a plurality of resonant waveguides formed in or on the semiconductor-based light absorbing material. The plurality of resonant waveguides is arranged in a pattern to cause laterally scattered light to be at least partially confined in the semiconductor-based light absorbing material.

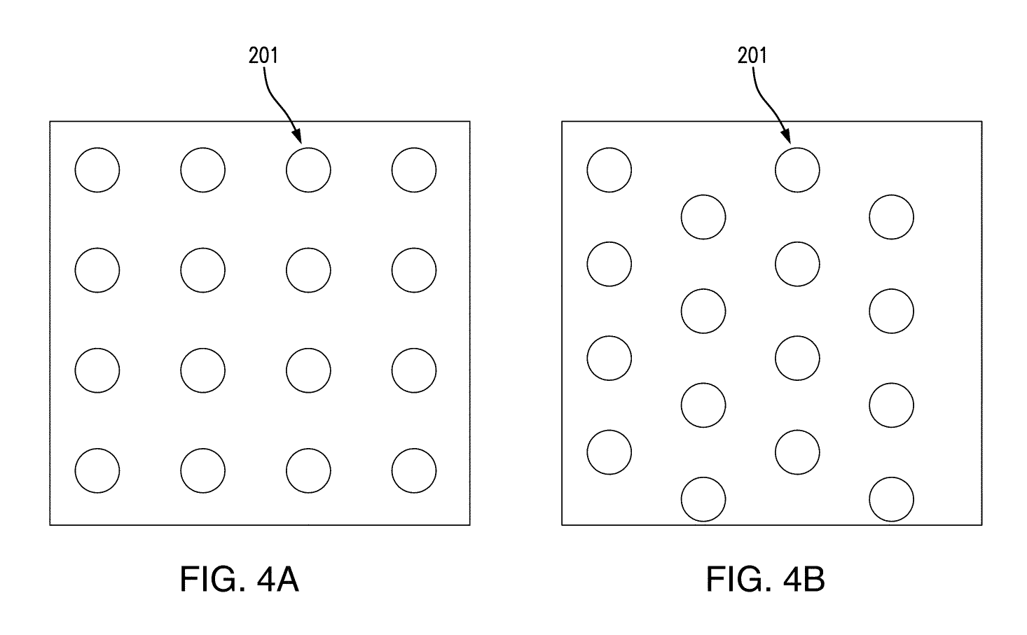

In one embodiment, the resonant waveguides are arranged in a repeating pattern. In various embodiments, the repeating pattern can be a staggered pattern of waveguides 201 (FIG. 4B) or an aligned pattern of waveguides 201 (FIG. 4A). In another embodiment, at least some of the resonant waveguides are ring-shaped or disc shaped. In another embodiment, at least some of the resonant waveguides have a regular polygon shape. In one embodiment, at least some of the resonant waveguides include at least two concentric rings.

In some embodiments, the ring-shaped waveguides may have multiple (more than two) concentric rings or a disc-shaped resonant waveguide may be surrounded by one or more waveguide rings. The gap between concentric rings can range from 0.01 μm to 10 μm, depending on the desired properties of the solar cell and manufacturing capabilities.

In one embodiment, a method of manufacturing a photovoltaic solar cell with a backside resonant photonic waveguide structure comprises forming a semiconductor substrate comprising at least one semiconductor-based light absorbing material that exhibits a photovoltaic effect, the semiconductor substrate having a front side and a backside, forming a backside structure comprising a plurality of resonant waveguides arranged in a pattern on the backside of the semiconductor bulk layer, forming at least one semiconductor surface layer on the front side of the semiconductor bulk layer, forming a top electrode on the semiconductor surface layer, and forming a bottom electrode on the backside structure.

In various embodiments, waveguides of different geometries may be combined on a solar cell. For example, a linear wave guide (e.g., an Si rib waveguide) may be combined with one or more ring-shaped waveguide whereby the linear waveguide (which typically does not provide infinite internal reflection) is configured to transmit light photos to the ring-shaped waveguide (which may provide infinite internal reflection. Waveguides may also be configured to direct light photos to other portions of the solar cell where different materials are deposited to leverage properties of those materials.

The photovoltaic cells described herein may be formed using conventional techniques known to those of skill in the art. As non-limiting examples, the structures described herein may be formed using photolithographic, chemical etching, or chemical vapor deposition techniques. The depth of the ONO stacks forming the resonant waveguides is determined by what is required to provide the amount of reflection to enhance solar cell performance. The depth/thickness of the waveguides can range from 150-2000 Å when the waveguide comprises the oxide-nitride-oxide stack. When the waveguide is in a solar cell that lacks the oxide-nitride-oxide stack, the depth/thickness of the waveguide can range from 1-5000 Å. In some embodiments the waveguide is 2000-3000 Å deep/thick.

In another embodiment, the method further comprises forming a first oxide layer on the backside structure, forming a silicon nitride layer on the first oxide layer, forming a second oxide layer on the nitride layer, and forming the bottom electrode on the second oxide layer.

In one embodiment, the method comprises etching the resonant waveguides into the semiconductor substrate. In another embodiment, the method comprises depositing the resonant waveguides onto the semiconductor substrate.

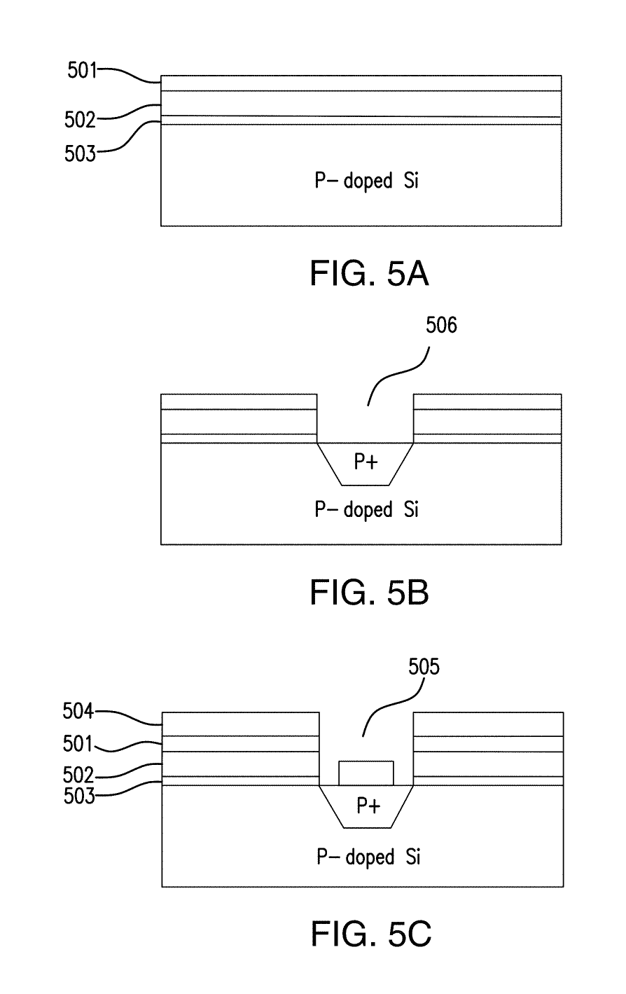

A representative process for manufacturing of an embodiment is depicted in FIGS. 5A-C. In FIG. 5A, a tunnel oxide layer 503 is grown or deposited on a P-doped Si layer. Subsequently, a nitride charge storage layer 502 is deposited on the tunnel oxide layer 503, followed by deposition of the capping oxide layer 501 on the nitride charge storage layer 502 to form an oxide-nitride-oxide stack. In FIG. 5B, openings 506 are etched in the oxide-nitride-oxide stack in a desired pattern to form discrete oxide-nitride-oxide stacks in the desired shape(s) of the resonant waveguides, such as oxide-nitride-oxide rings 203, 208 shown in FIGS. 3A, 3B, and P+ is implanted into the p-doped silicon. A base electrode 505 is deposited or etched, optionally in a shape conforming to the shapes of the ONO stacks, such as ring 206 shown in FIGS. 3A, 3B. Finally, a backside gate electrode 504 is deposited on each oxide-nitride-oxide stack. Back side gate electrode 504 can be made from any suitable material that is electrically conductive, such as, for example, aluminum. The base electrode 505 is patterned and etched to isolate the base electrode 505 from the gate electrode 504 and sintered to form a low resistance contact.

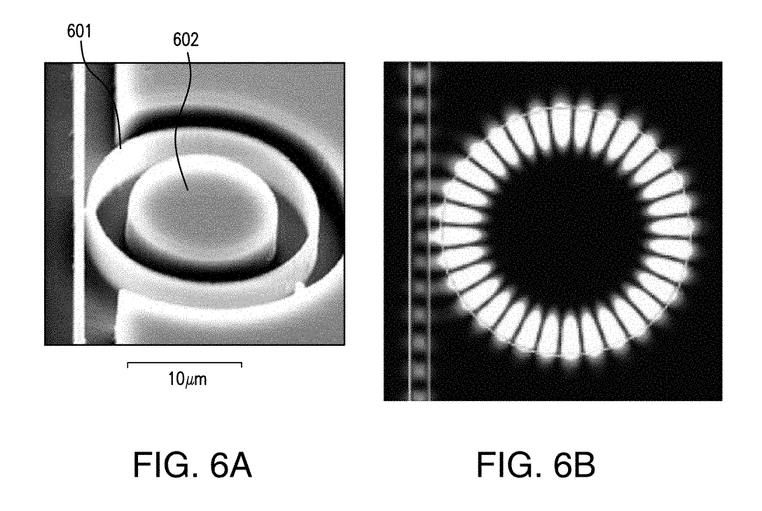

A device manufactured according to one embodiment is shown in FIG. 6A. FIG. 6A shows an AlGaAs-based 10-μm diameter optical ring resonator (e.g., similar to ring resonator 201 shown in FIGS. 3A, 3B. The coupling gap between the waveguide 602 and the ring 601 is approximately 100 nm. FIG. 6B depicts the optical modes in the resonator of FIG. 6A. The higher intensity (white) portions indicate modal confinement of the light in the ring.

While the subject matter of this disclosure has been described and shown in considerable detail with reference to certain illustrative embodiments, including various combinations and sub-combinations of features, those skilled in the art will readily appreciate other embodiments and variations and modifications thereof as encompassed within the scope of the present disclosure. Moreover, the descriptions of such embodiments, combinations, and sub-combinations is not intended to convey that the claimed subject matter requires features or combinations of features other than those expressly recited in the claims. Accordingly, the scope of this disclosure is intended to include all modifications and variations encompassed within the spirit and scope of the following appended claims.

We claim:

1. A method of manufacturing a photovoltaic solar cell with a backside resonant photonic waveguide structure, comprising:
a. forming a semiconductor substrate comprising at least one semiconductor-based light absorbing material that exhibits a photovoltaic effect, the semiconductor substrate having a front side and a backside;
b. forming a backside structure comprising a plurality of resonant waveguides arranged in a pattern on the backside of the semiconductor bulk layer;
c. forming at least one semiconductor surface layer on the front side of the semiconductor bulk layer;
d. forming a top electrode on the semiconductor surface layer; and
e. forming a bottom electrode on the backside structure.

2. The method of claim 1, further comprising:
a. forming a first oxide layer on the backside structure;
b. forming a silicon nitride layer on the first oxide layer;
c. forming a second oxide layer on the nitride layer; and
d. forming the bottom electrode on the second oxide layer.

3. The method of claim 1, wherein the resonant waveguides are etched into the semiconductor substrate.

4. The method of claim 1, wherein the resonant waveguides are deposited onto the semiconductor substrate.
